(19) United States
(12) Patent Application Publication
(10) Pub. No.: US 2015/0325700 A1
(43) Pub. Date: Nov. 12, 2015

(54) THIN FILM TRANSISTOR AND PIXEL STRUCTURE

(71) Applicant: Chunghwa Picture Tubes, LTD., Taoyuan (TW)

(72) Inventors: En-Chih Liu, Taoyuan County (TW); Ying-Hui Chen, Taoyuan County (TW); Ya-Ju Lu, New Taipei City (TW); Yen-Yu Huang, Taoyuan County (TW)

(21) Appl. No.: 14/453,616

(22) Filed: Aug. 7, 2014

(30) Foreign Application Priority Data
May 8, 2014 (TW) 103208055

(51) Int. Cl. H01L 29/786; H01L 29/04

(52) U.S. Cl. CPC H01L 29/7869; H01L 29/04

(57) ABSTRACT

A thin film transistor disposed above a carrying surface of a substrate is provided. The thin film transistor includes a gate, a first insulation layer, a channel, a source, a second insulation layer and a drain. The gate and the channel are overlapped with each other in a normal direction of the carrying surface. The first insulation layer is disposed between the channel and the gate. The source covers a portion of the channel and is electrically connected to the portion of the channel. The channel is located between the source and the first insulation layer in the normal direction. The source is disposed between the second insulation layer and the channel. The second insulation layer has a first hole exposing another portion of the channel. The drain is filled in the first hole and electrically connected to the another portion of the channel. Moreover, a pixel structure is provided.

### CROSS-REFERENCE TO RELATED APPLICATION

This application claims the priority benefit of Taiwan application Ser. No. 103208055, filed on May 8, 2014. The entirety of the above-mentioned patent application is hereby incorporated by reference herein and made a part of this specification.

### BACKGROUND OF THE INVENTION

1. Field of the Invention

The invention relates to an electronic device, and more particularly, to a thin film transistor and a pixel structure.

2. Description of Related Art

With the development of display technology, high-definition display panels have become the mainstream of modern-day display products. To manufacture the high-definition display panel, the area occupied by each pixel structure has to be reduced. Moreover, in view of transmittance of the display panel, it is preferred to make the area of a thin film transistor of each pixel structure as small as possible, so as to improve the aperture ratio of the display panel. In the prior art, the thin film transistor includes a gate, a source, a drain and a channel. The gate is overlapped with the channel. The source and the drain are in the same layer but are respectively disposed on two opposite sides of the channel. However, due to limitations on manufacturing capabilities, the minimum clearance between the source and the drain cannot be further reduced, making it difficult to further reduce the area occupied by the thin film transistor.

### SUMMARY OF THE INVENTION

The invention provides a thin film transistor and a pixel structure that occupy a small area.

The thin film transistor of the invention is disposed above a carrying surface of a substrate. The thin film transistor includes a gate, a channel, a first insulation layer, a source, a second insulation layer and a drain. The gate is disposed above the carrying surface of the substrate. The carrying surface has a normal direction that passes through the gate. The channel is disposed above the carrying surface of the substrate and overlapped with the gate in the normal direction. The first insulation layer is disposed between the channel and the gate. The source covers a portion of the channel and is electrically connected to the portion of the channel. The channel is located between the source and the first insulation layer in the normal direction. The source is disposed between the second insulation layer and the channel. The second insulation layer has a first hole. The first hole exposes another portion of the channel. The drain is filled in the first hole of the second insulation layer and electrically connected to the another portion of the channel. The second insulation layer is located between the drain and the source.

The pixel structure of the invention includes the aforementioned thin film transistor, and a pixel electrode electrically connected to the drain of the thin film transistor.

In an embodiment of the invention, the channel is located between the source and the substrate, and the gate is located between the channel and the substrate.

In an embodiment of the invention, a set of the source and the drain, and the gate, are respectively located on two different sides of the channel, and the gate is closer to the substrate than the set of the source and the drain.

In an embodiment of the invention, a normal projection of the source on the carrying surface substantially contacts with a normal projection of the drain on the carrying surface.

In an embodiment of the invention, materials of the channel include amorphous silicon or metal oxide semiconductors.

In an embodiment of the invention, the pixel structure further includes a third insulation layer. The third insulation layer is located between the pixel electrode and the drain. The third insulation layer has a second hole. The pixel electrode is filled in the second hole of the third insulation layer and electrically connected to the drain.

In an embodiment of the invention, the first hole and the second hole are substantially aligned with each other.

In an embodiment of the invention, the second insulation layer is a single layer, the pixel electrode directly covers the drain and the second insulation layer, and a portion of the pixel electrode exceeding the drain contacts with the second insulation layer.

Based on the above, in the thin film transistor and the pixel structure according to an embodiment of the invention, the source and the drain are disposed on the same side of the channel and in two different layers. Accordingly, the shortest distance between the source and the drain in a horizontal direction is not limited by manufacturing capabilities. In this way, the shortest distance between the source and the drain in the horizontal direction is smaller than the minimum achievable clearance in the same layer with current manufacturing capabilities. Accordingly, the thin film transistor is apparently reduced in size, which contributes to application of the pixel structure to a high-definition display panel.

To make the above features and advantages of the invention more comprehensible, embodiments accompanied with drawings are described in detail as follows.

### BRIEF DESCRIPTION OF THE DRAWINGS

FIG. 1A to FIG. 1G are schematic top views illustrating a manufacturing process of a pixel structure according to an embodiment of the invention.

FIG. 2A to FIG. 2G are schematic cross-sectional views illustrating a manufacturing process of a pixel structure, corresponding to the section line A-A′ in FIG. 1A to FIG. 1G respectively.

FIG. 3A is a schematic top view of a pixel structure according to another embodiment of the invention.

FIG. 3B is a schematic cross-sectional view of a pixel structure, corresponding to the section line B-B′ in FIG. 3A.

### DETAILED DESCRIPTION OF DISCLOSED EMBODIMENTS

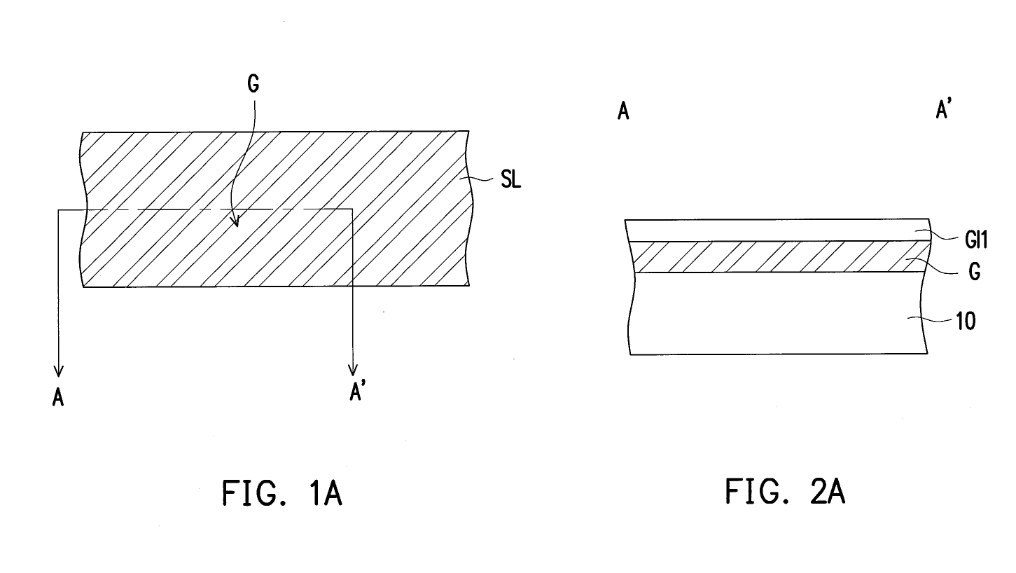

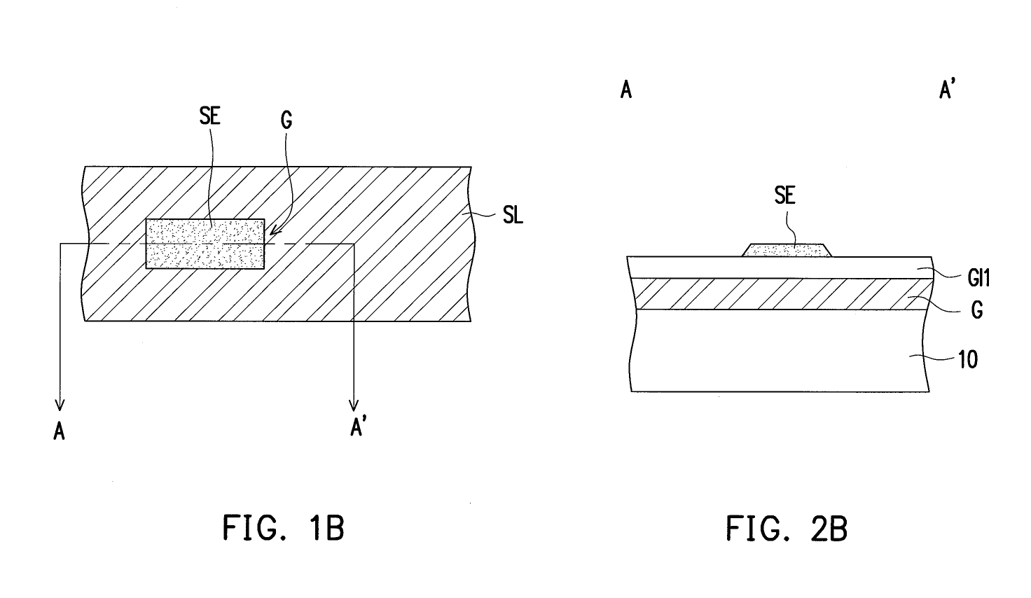

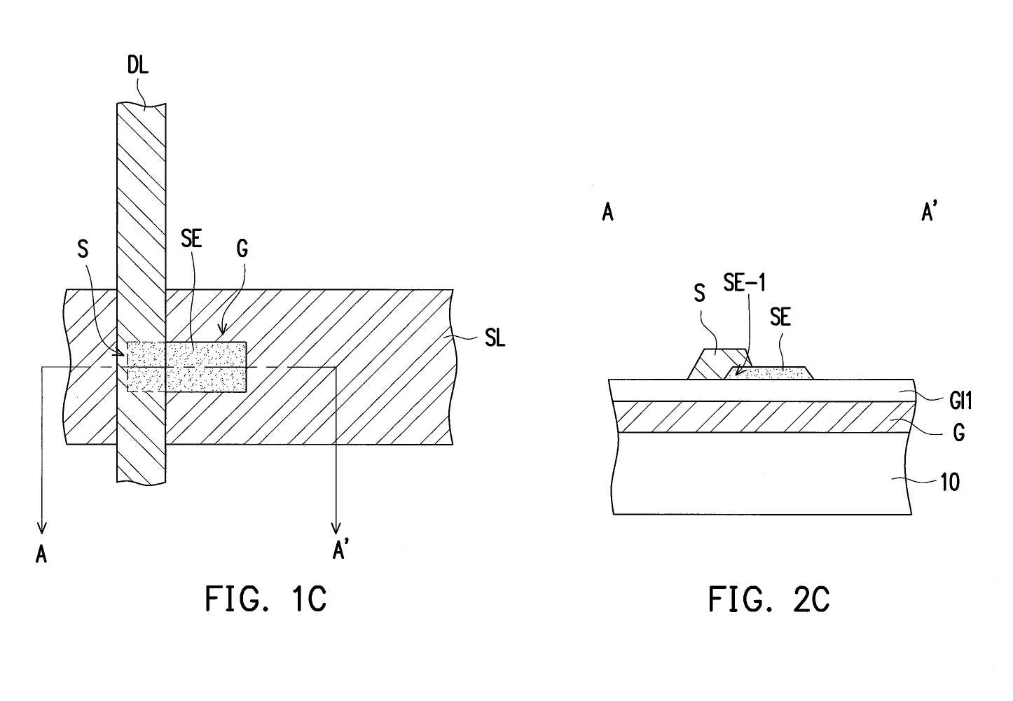

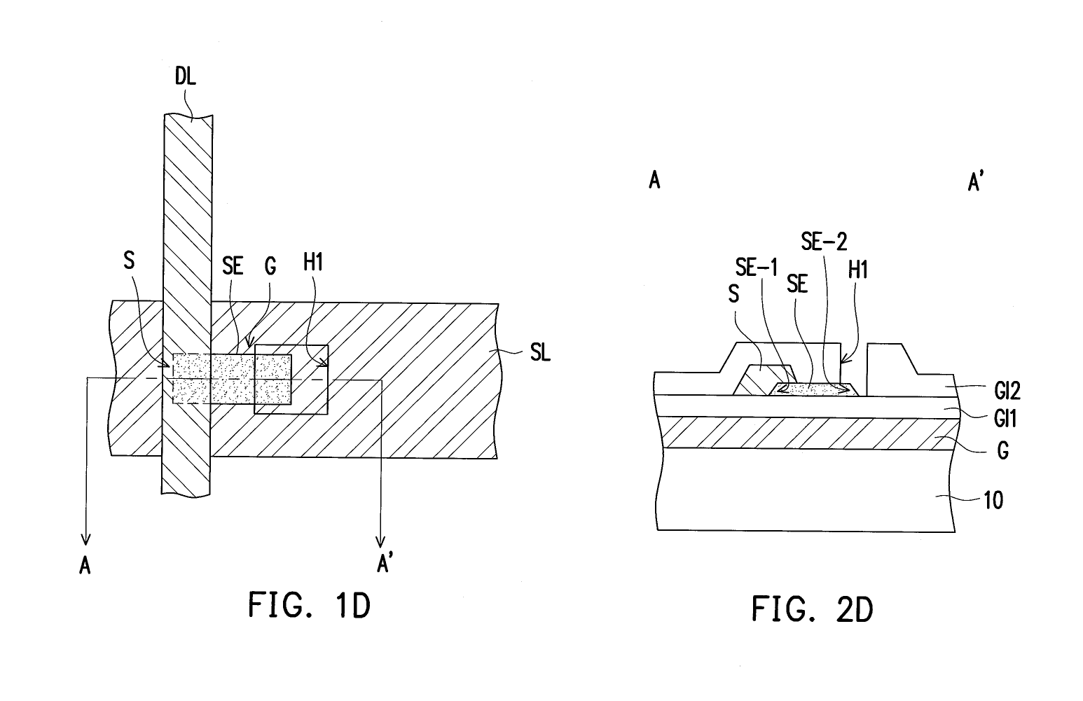

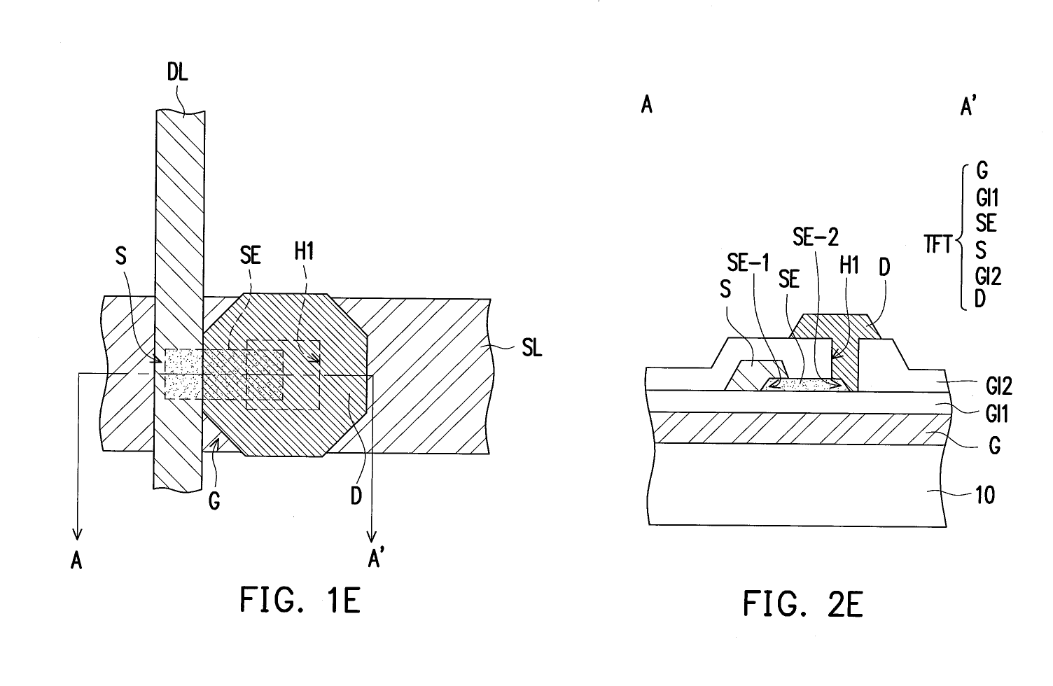

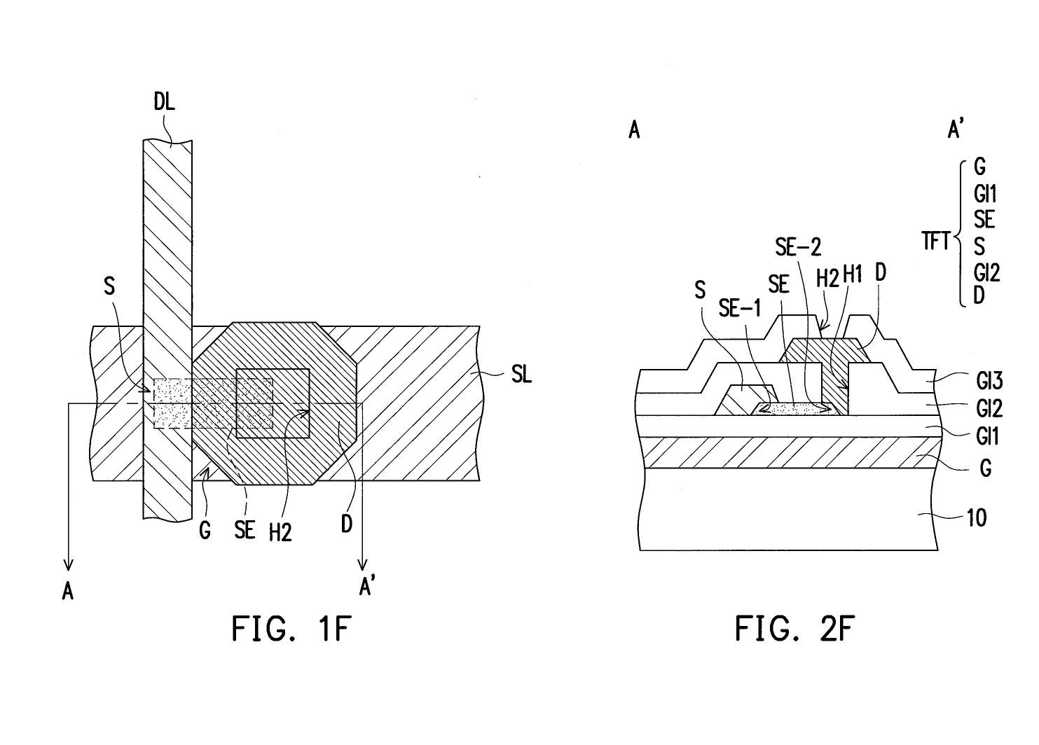

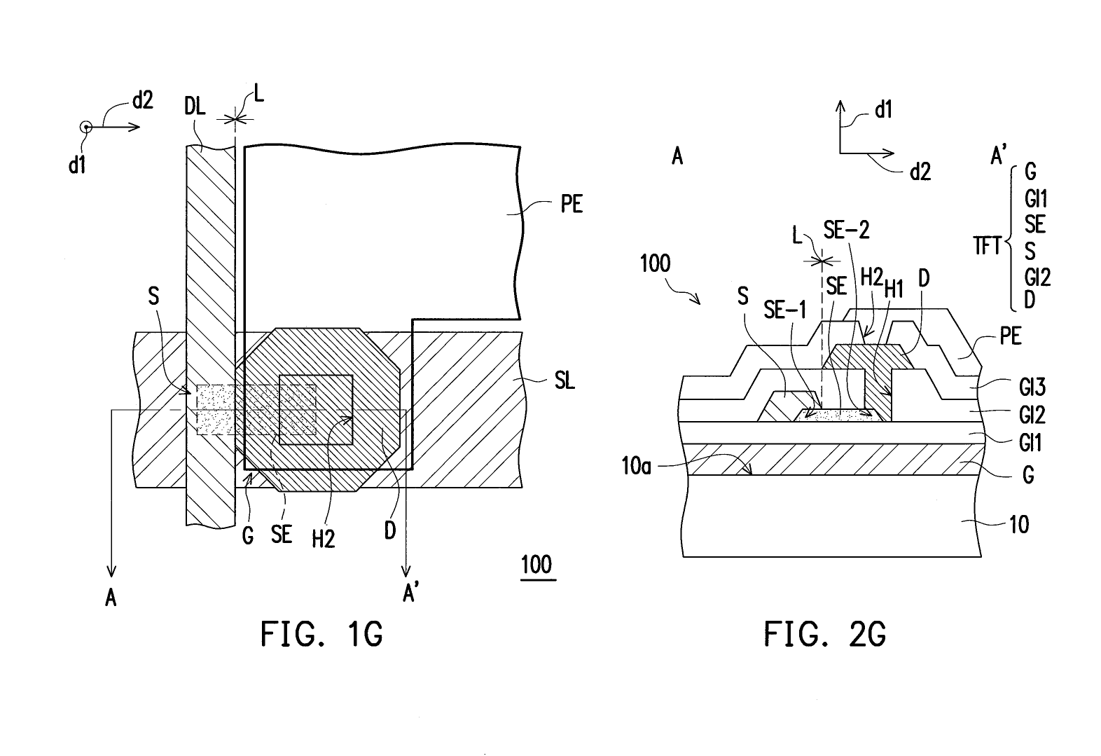

FIG. 1A to FIG. 1G are schematic top views illustrating a manufacturing process of a pixel structure according to an embodiment of the invention. FIG. 2A to FIG. 2G are schematic cross-sectional views illustrating a manufacturing process of a pixel structure, corresponding to the section line A-A′ in FIG. 1A to FIG. 1G respectively. It is to be noted that for clarity, a substrate 10 in FIG. 2A to FIG. 2G is omitted in FIG. 1A to FIG. 1G. Referring to FIG. 1A and FIG. 2A, first, the substrate 10 (shown in FIG. 2A) is provided. In terms of optical characteristics, the, substrate 10 is a transparent substrate or an opaque/reflective substrate. Materials of the transparent substrate are selected from glass, quartz, organic polymers, or other suitable materials or a combination thereof. Materials of the opaque/reflective substrate are selected from conductive materials, metals, wafers, ceramics, or other suitable materials or a combination thereof. It is to be noted that if the substrate 10 includes a conductive material, an insulation layer (not shown) has to be formed on the substrate 10 before a member of a pixel structure formed on the substrate 10, so as to avoid a short circuit between the substrate 10 and the member of the pixel structure. In terms of mechanical characteristics, the substrate 10 is a rigid substrate or a flexible substrate. Materials of the rigid substrate are selected from glass, quartz, conductive materials, metals, wafers, ceramics, or other suitable materials or a combination thereof. Materials of the flexible substrate are selected from ultrathin glass, organic polymers (e.g. plastics), or other suitable materials or a combination thereof.

Next, a gate G is formed on the substrate 10. As shown in FIG. 1B, in the present embodiment, a portion of a scan line SL is used as the gate G However, the invention is not limited thereto. In other embodiments, the gate G may be in other suitable forms, e.g., a conductive block formed by an outward extension of the scan line SL. Generally, the gate G includes a metal material. However, the invention is not limited thereto. In other embodiments, the gate G may include other conductive materials (e.g. alloys, nitrides of metal materials, oxides of metal materials, oxynitrides of metal materials, etc.), or a stacked layer of metal materials and other conductive materials. Next, a first insulation layer GI1 (shown in FIG. 2A) is formed. Materials of the first insulation layer GI1 are selected from inorganic materials (e.g. silicon oxide, silicon nitride, silicon oxynitride, or other suitable materials, or a stacked layer of at least two of the above materials), organic materials, or other suitable materials, or a combination of the above.

Referring to FIG. 1B and FIG. 2B, next, a channel SE is formed on the first insulation layer GI1. In detail, in the present embodiment, a pre-channel (not shown) is formed on the first insulation layer GI1, followed by performing an annealing process on the pre-channel to form the channel SE. By the annealing process, the channel SE is considerably improved in electrical characteristics such as carrier mobility. The channel SE has a single-layer or multilayer structure, and materials thereof are selected from amorphous silicon, polysilicon, microcrystalline silicon, monocrystalline silicon, metal-oxide-semiconductor materials [e.g. indium-gallium-zinc oxide (IGZO), zinc oxide (ZnO), tin oxide (SnO), indium-zinc oxide (IZO), gallium-zinc oxide (GZO), zinc-tin oxide (ZTO), indium-tin oxide (ITO), etc.], or other suitable materials, or a combination of the above.

Referring to FIG. 1C and FIG. 2C, next, a source S is formed on the channel SE. The source S covers a portion SE-1 (shown in FIG. 2C) of the channel SE and is electrically connected to the portion SE-1 of the channel SE. In the present embodiment, as shown in FIG. 1C, a portion of a data line DL is used as the source S. However, the invention is not limited thereto. In other embodiments, the source S may be in other suitable forms, e.g., a conductive block formed by an extension of the data line DL toward the channel SE. Generally, the source S includes a metal material. However, the invention is not limited thereto. In other embodiments, the source S may include other conductive materials (e.g. alloys, nitrides of metal materials, oxides of metal materials, oxynitrides of metal materials, etc.), or a stacked layer of metal materials and other conductive materials.

Referring to FIG. 1D and FIG. 2D, next, a second insulation layer GI2 (shown in FIG. 2D) is formed on the source S. The second insulation layer GI2 covers the source S, the portion SE-1 of the channel SE, and the first insulation layer GI1, and has a first hole H1 exposing another portion SE-2 of the channel SE. Materials of the second insulation layer GI2 are selected from inorganic materials (e.g. silicon oxide, silicon nitride, silicon oxynitride, or other suitable materials, or a stacked layer of at least two of the above materials), organic materials, or other suitable materials, or a combination of the above.

Referring to FIG. 1E and FIG. 2E, next, a drain D is formed on the second insulation layer GI2. The drain D is filled in the first hole H1 of the second insulation layer GI2 and electrically connected to the another portion SE-2 of the channel SE. Accordingly, a thin film transistor TFT (shown in FIG. 2E) of the present embodiment is completed. Generally, the drain D includes a metal material. However, the invention is not limited thereto. In other embodiments, the drain D may include other conductive materials (e.g. alloys, nitrides of metal materials, oxides of metal materials, oxynitrides of metal materials, etc.), or a stacked layer of metal materials and other conductive materials.

Referring to FIG. 1F and FIG. 2F, next, in the present embodiment, a third insulation layer GI3 (shown in FIG. 2F) is selectively formed on the drain D. The third insulation layer GI3 covers a portion of the drain D and the second insulation layer GI2. The third insulation layer GI3 has a second hole H2. The second hole H2 exposes another portion of the drain D. Materials of the third insulation layer GI3 are selected from inorganic materials (e.g. silicon oxide, silicon nitride, silicon oxynitride, or other suitable materials, or a stacked layer of at least two of the above materials), organic materials, or other suitable materials, or a combination of the above.

Referring to FIG. 1G and FIG. 2G, next, a pixel electrode PE is formed on the drain D. In the present embodiment, the pixel electrode PE is filled in the second hole H2 of the third insulation layer GI3 and electrically connected to the drain D. Accordingly, a pixel structure 100 of the present embodiment is completed. The pixel electrode PE may be designed to be a transmissive pixel electrode, a reflective pixel electrode or a transflective pixel electrode, depending on actual needs. Materials of the transmissive pixel electrode include metal oxides, e.g. indium tin oxide, indium zinc oxide, aluminum tin oxide, aluminum zinc oxide, indium germanium zinc oxide, or other suitable oxides, or a stacked layer of at least two of the above. Materials of the reflective pixel electrode include conductive materials having high reflectivity, e.g. metals, etc. Materials of the transflective pixel electrode include a combination of conductive materials having high reflectivity and conductive materials having high transmittance.

The pixel structure 100 is disposed above a carrying surface 10a (shown in FIG. 2G) of the substrate 10. The pixel structure 100 includes the thin film transistor TFT, and the pixel electrode PE electrically connected to the drain D of the thin film transistor TFT. The thin film transistor TFT includes the gate G, the first insulation layer GI1, the channel SE, the source S, the second insulation layer GI2 and the drain D. The carrying surface 10a of the substrate 10 has a normal direction d1 that passes through the gate G In detail, if the carrying surface 10a is a plane, the normal direction d1 refers to a direction perpendicular to the carrying surface 10a. If the carrying surface 10a is a curved surface, the normal direction d1 refers to a direction perpendicular to a reference tangent plane (not shown), wherein the reference tangent plane is tangential to the carrying surface 10a and passes through a location of the gate G.

The gate G and the channel SE are both disposed above the carrying surface 10a of the substrate 10. The channel SE and the gate G are overlapped with each other in the normal direction d1. The first insulation layer GI1 (shown in FIG. 2G) is disposed between the channel SE and the gate G In the present embodiment, the first insulation layer GI1 completely covers the gate G and the substrate 10, so as to present a complete insulating pattern. However, the invention is not limited thereto. The pattern of the first insulation layer GI1 may be designed in other suitable ways depending on actual needs.

The source S covers the portion SE-1 of the channel SE and is electrically connected to the portion SE-1 of the channel SE. The channel SE is located between the source S and the first insulation layer GI1 in the normal direction d1. In the present embodiment, the source S directly covers the portion SE-1 of the channel SE and electrically contacts with the portion SE-1 of the channel SE. However, the invention is not limited thereto. In other embodiments, the source S may be electrically connected to the portion SE-1 of the channel SE via an ohmic contact layer (not shown) or in other suitable ways.

The second insulation layer GI2 covers the source S, and the portion SE-1 of the channel SE. The source S is disposed between the second insulation layer GI2 and the channel SE. The second insulation layer GI2 has the first hole H1. The first hole H1 exposes the another portion SE-2 of the channel SE. The drain D is filled in the first hole H1 of the second insulation layer G12 and electrically connected to the another portion SE-2 of the channel SE. In the present embodiment, a portion of the drain D directly covers the another portion SE-2 of the channel SE and electrically contacts with the another portion SE-2 of the channel SE. However, the invention is not limited thereto. In other embodiments, the drain D may be electrically connected to the another portion SE-2 of the channel SE via an ohmic contact layer (not shown) or in other suitable ways.

In the present embodiment, the channel SE is selectively located between the source S and the substrate 10, and the gate G is selectively located between the channel SE and the substrate 10. A set of the source S and the drain D, and the gate G, are respectively located on two different sides of the channel SE. The gate G is selectively closer to the substrate 10 than the set of the source S and the drain D. In other words, the thin film transistor TFT of the present embodiment is selectively designed to be a bottom gate thin film transistor. However, the invention is not limited thereto. In other embodiments, the thin film transistor may be designed to be a top gate type or in other suitable forms.

In the present embodiment, the pixel structure 100 selectively includes the third insulation layer GI3. The third insulation layer GI3 is located between the pixel electrode PE and the drain D. The third insulation layer GI3 has the second hole H2. The pixel electrode PE is filled in the second hole H2 and electrically connected to the drain D. It is worth mentioning that in the present embodiment, the first hole H1 and the second hole H2 are substantially aligned with each other. In other words, the first hole H1 and the second hole H2 are disposed above the same block of the substrate 10, instead of being disposed at two different positions. Accordingly, the thin film transistor TFT is further reduced in size.

It should be noted that in the pixel structure 100 and the thin film transistor TFT, the source S is disposed between the second insulation layer GI2 and the channel SE, and the second insulation layer GI2 is disposed between the drain D and the source S. In other words, the source S and the drain D are located on the same side of the channel SE but in two different layers. Thus, a shortest distance L between the source S and the drain D in a horizontal direction d2 perpendicular to the normal direction d1 is not constrained by limitations on the minimum achievable clearance in the same layer with current manufacturing capabilities. At this moment, the shortest distance L between the source S and the drain D in the horizontal direction d2 is apparently smaller than the minimum achievable clearance in the same layer with current manufacturing capabilities. Accordingly, an area occupied by the thin film transistor TFT is noticeably reduced, which contributes to application of the pixel structure 100 to a high-definition display panel.

For example, in the present embodiment, a normal projection of the source S on the carrying surface 10a substantially contacts with a normal projection of the drain D on the carrying surface 10a. More specifically, as shown in FIG. 1G, in the present embodiment, the normal projection of the source S on the carrying surface 10a and the normal projection of the drain D on the carrying surface 10a are just adjacent to but not overlapped with each other. That is, the shortest distance L between the source S and the drain D in the horizontal direction d2 is reduced to 0. It is to be noted that the invention is not limited to the case where the normal projection of the source S on the carrying surface 10a and the normal projection of the drain D on the carrying surface 10a are just adjacent to each other. In other embodiments, the normal projection of the source S on the carrying surface 10a and the normal projection of the drain D on the carrying surface 10a may be separate from or overlapped with each other. All those thin film transistors and pixel structures that include the source and the drain located on the same side of the channel and in two different layers to reduce the shortest distance between the source and the drain in the horizontal direction fall within the scope for which protection is sought by the invention.

In addition, it is further worth mentioning that as shown in FIG. 2B to FIG. 2E, in an embodiment of the invention, the source S and the drain D are formed after fabrication of the channel SE. Therefore, when an annealing process is performed on the pre-channel (not shown) to form the channel SE, the high temperature during the annealing process has no influence on the source S and the drain D, and thus no oxidation occurs. Accordingly, the thin film transistor TFT and the pixel structure 100 of the present embodiment further have an advantage of excellent and stable quality.

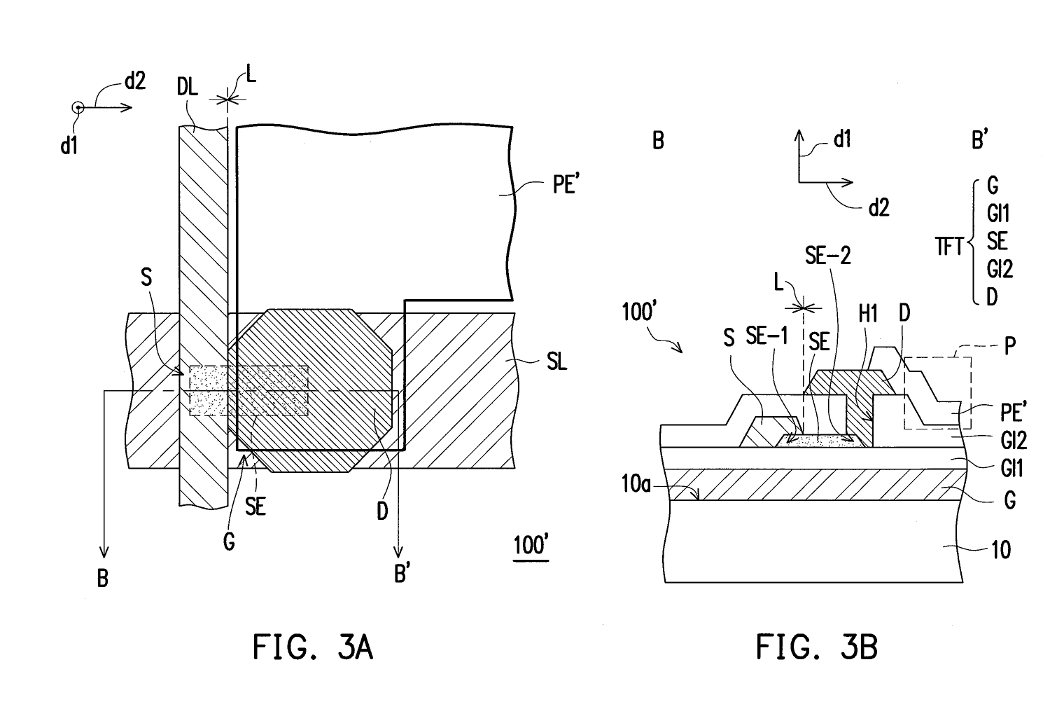

FIG. 3A is a schematic top view of a pixel structure according to another embodiment of the invention. FIG. 3B is a schematic cross-sectional view of a pixel structure, corresponding to the section line B-B′ in FIG. 3A. It is to be noted that for clarity, the substrate 10 in FIG. 3B is omitted in FIG. 3A. Referring to FIG. 3A and FIG. 3B, a pixel structure 100′ in FIG. 3A and FIG. 3B is similar to the pixel structure 100 in FIG. 1G and FIG. 2G, and thus the same or corresponding elements are represented by the same or corresponding reference numerals. A main difference between the pixel structure 100′ and the pixel structure 100 is that the pixel structure 100′ does not have the third insulation layer GI3 that is included in the pixel structure 100. The following mainly describes this difference, and the descriptions of the same elements will not be repeated.

Referring to FIG. 3A and FIG. 3B, the pixel structure 100′ is disposed above the carrying surface 10a of the substrate 10. The pixel structure 100′ includes the thin film transistor TFT, and a pixel electrode PE′ electrically connected to the drain D of the thin film transistor TFT. The thin film transistor TFT includes the gate G, the first insulation layer GI1, the channel SE, the source S, the second insulation layer GI2 and the drain D. The gate G is disposed above the carrying surface 10a of the substrate 10. The carrying surface 10a has the normal direction d1 that passes through the gate G The channel SE is disposed above the carrying surface 10a of the substrate 10, and is overlapped with the gate G in the normal direction d1 of the carrying surface 10a. The first insulation layer GI1 is disposed between the channel SE and the gate G The source S covers the portion SE-1 of the channel SE and is electrically connected to the portion SE-1 of the channel SE. The channel SE is located between the source S and the first insulation layer GI1 in the normal direction d1. The source S is disposed between the second insulation layer GI2 and the channel SE. The second insulation layer GI2 has the first hole H1. The first hole H1 exposes the another portion SE-2 of the channel SE. In the embodiment of FIG. 3B, the second insulation layer GI2 is, e.g., a single layer. However, the invention is not limited thereto. In other embodiments, the second insulation layer may be formed by stacking a plurality of insulation layers. The drain D is filled in the first hole H1 of the second insulation layer GI2 and electrically connected to the another portion SE-2 of the channel SE. The second insulation layer GI2 is located between the drain D and the source S. The pixel structure 100′ differs from the pixel structure 100 in that the pixel structure 100′ does not include the third insulation layer GI3, and that the pixel electrode PE′ directly covers the drain D and the second insulation layer GI2. More specifically, a portion P (shown in FIG. 3B) of the pixel electrode PE′ exceeding the drain D contacts with the second insulation layer GI2.

The pixel structure 100′ has the same advantages as the pixel structure 100, and in addition, because the pixel structure 100′ excludes the third insulation layer GI3, the number of masks required for the manufacture of the pixel structure 100′ is one fewer than that for the manufacture of the pixel structure 100. Therefore, the pixel structure 100′ is more advantageous in terms of low manufacturing cost.

In summary, in the thin film transistor and the pixel structure according to an embodiment of the invention, the source and the drain are disposed on the same side of the channel and in two different layers. Accordingly, the shortest distance between the source and the drain in the horizontal direction is not limited by manufacturing capabilities. In this way, the shortest distance between the source and the drain in the horizontal direction is smaller than the minimum achievable clearance in the same layer with current manufacturing capabilities. Accordingly, the area occupied by the thin film transistor is apparently reduced, which contributes to application of the pixel structure to a high-definition display panel.

What is claimed is:

1. A thin film transistor disposed above a carrying surface of a substrate, the thin film transistor comprising:
a gate disposed above the carrying surface of the substrate, the carrying surface having a normal direction that passes through the gate;
a channel disposed above the carrying surface of the substrate and overlapped with the gate in the normal direction;
a first insulation layer disposed between the channel and the gate;
a source covering a portion of the channel and electrically connected to the portion of the channel, the channel being located between the source and the first insulation layer in the normal direction;
a second insulation layer, the source being disposed between the second insulation layer and the channel, the second insulation layer having a first hole, the first hole exposing another portion of the channel; and
a drain filled in the first hole of the second insulation layer and electrically connected to the another portion of the channel, the second insulation layer being located between the drain and the source.

2. The thin film transistor according to claim 1, wherein the channel is located between the source and the substrate, and the gate is located between the channel and the substrate.

3. The thin film transistor according to claim 1, wherein a set of the source and the drain, and the gate, are respectively located on two different sides of the channel, and the gate is closer to the substrate than the set of the source and the drain.

4. The thin film transistor according to claim 1, wherein a normal projection of the source on the carrying surface contacts with a normal projection of the drain on the carrying surface.

5. The thin film transistor according to claim 1, wherein materials of the channel comprise amorphous silicon or metal oxide semiconductors.

6. A pixel structure disposed above a carrying surface of a substrate, the pixel structure comprising:
a thin film transistor comprising:
a gate disposed above the carrying surface of the substrate, the carrying surface having a normal direction that passes through the gate;
a channel disposed above the carrying surface of the substrate and overlapped with the gate in the normal direction of the carrying surface;
a first insulation layer disposed between the channel and the gate;
a source covering a portion of the channel and electrically connected to the portion of the channel, the channel being located between the source and the first insulation layer in the normal direction;
a second insulation layer, the source being disposed between the second insulation layer and the channel, the second insulation layer having a first hole, the first hole exposing another portion of the channel; and
a drain filled in the first hole of the second insulation layer and electrically connected to the another portion of the channel, the second insulation layer being located between the drain and the source; and
a pixel electrode electrically connected to the drain of the thin film transistor.

7. The pixel structure according to claim 6, further comprising:
a third insulation layer located between the pixel electrode and the drain, the third insulation layer having a second hole, the pixel electrode being filled in the second hole of the third insulation layer and electrically connected to the drain.

8. The pixel structure according to claim 7, wherein the first hole and the second hole are aligned with each other.

9. The pixel structure according to claim 6, wherein the second insulation layer is a single layer, the pixel electrode directly covers the drain and the second insulation layer, and a portion of the pixel electrode exceeding the drain contacts with the second insulation layer.

10. The pixel structure according to claim 6, wherein a set of the source and the drain, and the gate, are respectively located on two different sides of the channel, and the gate is closer to the substrate than the set of the source and the drain.
